(19) United States
(12) Patent Application Publication
(10) Pub. No.: US 2025/0062091 A1
(43) Pub. Date: Feb. 20, 2025

(54) AC Pulse Control of PCM Switch

(71) Applicant: Murata Manufacturing Co., Ltd., Kyoto (JP)

(72) Inventors: Jean-Luc Erb, San Diego, CA (US); Bryan Lee Hash, Lake Zurich, IL (US); Jeffrey A. Dykstra, Woodstock, IL (US)

(21) Appl. No.: 18/452,089

(22) Filed: Aug. 18, 2023

(51) Int. Cl. H01H 35/00; H03K 17/687; H10N 70/00; H10N 70/20

(52) U.S. Cl. CPC H01H 35/00; H03K 17/6871; H10N 70/231; H10N 70/823; H10N 70/8413

(57) ABSTRACT

Circuits and methods for increasing the long-term reliability and performance of phase change material (PCM) switches. To overcome the effects of electromigration damage of the resistive heater(s) of a PCM switch and of the PCM itself, and thus improve long-term performance and reliability, embodiments apply an AC control pulse of equal power to a conventional DC control pulse. An embodiment encompasses a PCM switch, including a PCM region including first and second signal ports configured to be coupled to a signal source; a resistive heater adjacent the PCM region and including first and second heater control signal ports; and a source of AC control pulses coupled to the first and second heater control signal ports, the AC control pulses having a first power profile to transform the PCM region into a low resistance state and a second power profile to transform the PCM region into a high resistance state.

### BACKGROUND

### (1) Technical Field

This invention relates to electronic circuits, and more particularly to electronic integrated circuits that include phase change material (PCM) switches.

### (2) Background

Phase-change materials have been used to fabricate integrated circuit (IC) switches that include a channel that can be thermally transitioned between a high-resistivity amorphous OFF state (e.g., having a resistivity p of about 10 Ω-m) and a low-resistivity crystalline ON state (e.g., having a resistivity p of less than about 2 μΩ-m). A PCM switch consists of a volume of phase-change material (PCM) having two electrical terminals on opposite sides of the PCM ON/OFF channel, and an adjacent resistive heater. The phase-change material may be made of a chalcogenide alloy—examples include germanium-antimony-tellurium (GeSbTe), germanium-tellurium (GeTe), and germanium-antimony (GeSb). The resistive heater may be made of a metal (e.g., copper, aluminum, nickel-chromium, or tungsten) or of any other material compatible with IC fabrication and which heats when subjected to electrical power.

FIG. 1A is a diagram of a prior art electrical symbol 100 for a PCM switch, and a (roughly) equivalent single-pole, single-throw switch symbol 102. The electrical symbol 100 stylistically shows a region of PCM 104 (marked with a “delta” symbol to indicate “change”) and an adjacent resistive heater R_{H}. The PCM 104 has ports RF1 and RF2, which may be coupled, for example, to a radio frequency (RF) signal source (e.g., an antenna). The resistive heater R_{H} has ports P1 and P2, which may be coupled to a suitable source 106 of DC control pulses. Precisely controlled electrical power profiles are applied to the resistive heater R_{H} to generate different thermal profiles that result in transforming the region of PCM 104 by amorphizing the PCM region 104 into a high resistance state (OFF or open) using a higher-power, short-period pulse, or by crystalizing the PCM region 104 into a low resistance state (ON or closed) using a lower-power, long-period pulse.

FIG. 1B is a stylized cross-sectional view of a portion of a prior art IC showing the physical structure of a PCM switch 110. Within an insulating layer 112, a region of PCM 114 is formed and connected to two electrical contacts (e.g., vias) 116. At least one resistive heater 118 is formed in close enough proximity to the PCM region 114 to be able to either crystalize or amorphize the ON/OFF channel of the PCM region 114; in the illustrated example, two resistive heaters 118 are shown, bracketing the PCM region 114. Not shown are electrical contacts to the resistive heaters 118, which may be coupled to a driver circuit that is controlled to provide different power profiles corresponding to the different thermal profiles required to switch the ON and OFF resistivity states of the PCM region 114.

FIG. 2A is a graph of an example of two different power profiles for switching the resistivity states of the PCM region 114 of FIG. 1B. FIG. 2B is a graph of an example of the corresponding thermal profiles that cause switching of the resistivity states of the PCM region 114 of FIG. 1B. (Note that while the power profiles illustrated in FIG. 2A are essentially square waves, in practice there is some ramp-up and ramp-down time (generally brief) for the applied power.)

Referring to both FIGS. 2A and 2B, in order to place the PCM switch 110 of FIG. 1B in an OFF state, a higher-power, short-period electrical pulse 202 is applied to the resistive heaters 118. The electrical pulse 202 provides a power level sufficient to cause the temperature profile of the PCM region 114 to rapidly increase above a melting temperature Tm for the selected phase-change material, resulting in a thermal profile 204 for the PCM region 114 that exhibits a rapid increase and then a rapid decrease in temperature. For some PCM, Tm is about 700°-750° C.

Again referring to both FIGS. 2A and 2B, in order to place the PCM switch 110 of FIG. 1B in an ON state, a lower-power, long-period electrical pulse 206 is applied to the resistive heaters 118. The electrical pulse 206 provides a power level sufficient to cause the temperature profile of the PCM region 114 to increase above a crystallization (or recrystallization) temperature Tc (less than Tm) for the selected phase-change material for a longer period of time, resulting in a thermal profile 208 for the PCM region 114 that exhibits a slower, lower, and longer increase in temperature compared to the OFF state thermal profile 204. The ON state electrical pulse 206 may be, for example, about 7 times longer than the OFF state electrical pulse 202 (e.g., ˜1000 ns versus ˜150 ns). For some PCM, Tc is about 150°-200° C.

FIG. 3 is a cross-section diagram of a monolithic silicon-on-insulator (SOI) IC 300 that includes a PCM switch. In the illustrated example, a substrate 302 (e.g., sapphire, trap rich Si, or high resistivity Si) supports a substructure 304 comprising a buried oxide (BOX) insulator layer 306 which supports an active layer 308. In the illustrated example, each CMOS device comprises two metal-oxide semiconductor field-effect transistors (MOSFETs), an nFET and a pFET, formed in and on the active layer 308. Each MOSFET includes a source S, drain D, and gate G. A superstructure 310 is formed on the active layer 308, and generally comprises inter-layer dielectric (ILD) with formed layers of conductive material (e.g., metallization layers M1, M2, M3, etc.), and vertical conductors (vias) 312. In the illustrated example, the superstructure 310 also includes a PCM switch 314 comprising a patterned PCM region 316 with an adjacent resistive heater R_{H} 318. The patterned PCM region 316 is thus an “island” of PCM surrounded by ILD (there may be multiple instances of PCM switches 314, each including an “island” patterned PCM region 316). In some embodiments, vertical conductors (vias) 320 may connect to the patterned PCM region 316 to enable external connections to the PCM switch 314. In other embodiments, electrical connections to the PCM switch 314 may be entirely internal within the superstructure 310 or may include both internal and external electrical connections. The superstructure 310 may include additional layers of ILD and metallization above the PCM switch 314.

PCM switches are fast, non-volatile, have power consumption on par with field-effect transistor (FET) switches at low switching rates (e.g., 10 Hz), have a relatively small form factor, and can be readily integrated with complementary metal-oxide semiconductor (CMOS) technology. As such, PCM switches have a great potential for implementing high-speed RF switch networks. However, use of PCM switches in RF switch networks is not without drawbacks. The inventors have identified a significant problem with long-term reliability and performance of PCM switches, which the present invention addresses.

### SUMMARY

The present invention encompasses circuits and methods for increasing the long-term reliability and performance of phase change material (PCM) switches. In particular, to overcome the effects of electromigration damage of the resistive heater(s) of a PCM switch and of the PCM layer itself, and thus improve long-term radio frequency (RF) performance and reliability, embodiments of the present invention apply an AC control pulse of equal power to a conventional DC control pulse.

An embodiment of the present invention encompasses a phase change material (PCM) switch, including: a PCM region including first and second signal ports configured to be coupled to a signal source; a resistive heater adjacent the PCM region and including first and second heater control signal ports; and a source of AC control pulses coupled to the first and second heater control signal ports, the AC control pulses having a first power profile to transform the PCM region into a low resistance state, and a second power profile to transform the PCM region into a high resistance state.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a diagram of a prior art electrical symbol for a PCM switch, and a (roughly) equivalent single-pole, single-throw switch symbol.

FIG. 1B is a stylized cross-sectional view of a portion of a prior art IC showing the physical structure of a PCM switch.

FIG. 2A is a graph of an example of two different power profiles for switching the resistivity states of the PCM region of FIG. 1B.

FIG. 2B is a graph of an example of the corresponding thermal profiles that cause switching of the resistivity states of the PCM region of FIG. 1B.

FIG. 3 is a cross-section diagram of a monolithic silicon-on-insulator (SOI) IC that includes a PCM switch.

FIG. 4 is a stylized cross-section of a PCM switch in a pristine condition. In the illustrated example, a resistive heater is positioned below a PCM layer.

FIGS. 5A and 5B are stylized cross-sections of two different PCM switches, after failure due to electromigration.

FIG. 6 is a schematic diagram of a PCM switch including a source of AC control pulses in accordance with the present invention.

FIG. 7A shows a graph of applied current as a function of time for AC control pulses comprising a sequence of rectangular waves.

FIG. 7B shows a graph of applied current as a function of time for AC control pulses comprising a sequence of sinusoidal waves.

FIG. 7C shows a graph of applied current as a function of time for AC control pulses comprising a sequence of sawtooth waves.

FIG. 7D shows a graph of applied current as a function of time for AC control pulses comprising a sequence of triangular waves.

FIG. 8A shows an example sinusoidal waveform superimposed over the DC “OFF” control pulse from FIG. 2A.

FIG. 8B shows an example sinusoidal waveform superimposed over the DC “ON” control pulse from FIG. 2B.

FIG. 9 is a schematic diagram of a first driver circuit for generating AC control pulses for a resistive heater of a PCM switch.

FIG. 10 is a schematic diagram of a second driver circuit for generating AC control pulses for a resistive heater of a PCM switch.

FIG. 11 is a schematic diagram of a third driver circuit for generating AC control pulses for a resistive heater of a PCM switch.

FIG. 12 is a schematic diagram of a fourth driver circuit for generating AC control pulses for a resistive heater of a PCM switch.

FIG. 13A is a schematic diagram of a fifth driver circuit for generating AC control pulses for a resistive heater of a PCM switch.

FIG. 13B is a schematic diagram of the driver circuit shown during a first half cycle, with switch pair S1/S3 closed and switch pair S2/S4 open.

FIG. 13C is a schematic diagram of the driver circuit shown during a second half cycle, with switch pair S1/S3 open and switch pair S2/S4 closed.

FIG. 14 is a schematic diagram of a sixth driver circuit for generating AC control pulses for a resistive heater of a PCM switch.

FIG. 15 is a schematic diagram of a seventh driver circuit for generating AC control pulses for a resistive heater of a PCM switch.

FIG. 16A is a schematic layout diagram of a pair of PCM switches with RF ports connected in series and corresponding resistive heaters connected in series.

FIG. 16B is a schematic layout diagram of a pair of PCM switches with RF ports connected in parallel and corresponding resistive heaters connected in series.

FIG. 17 is a top plan view of a substrate that may be, for example, a printed circuit board or chip module substrate (e.g., a thin-film tile).

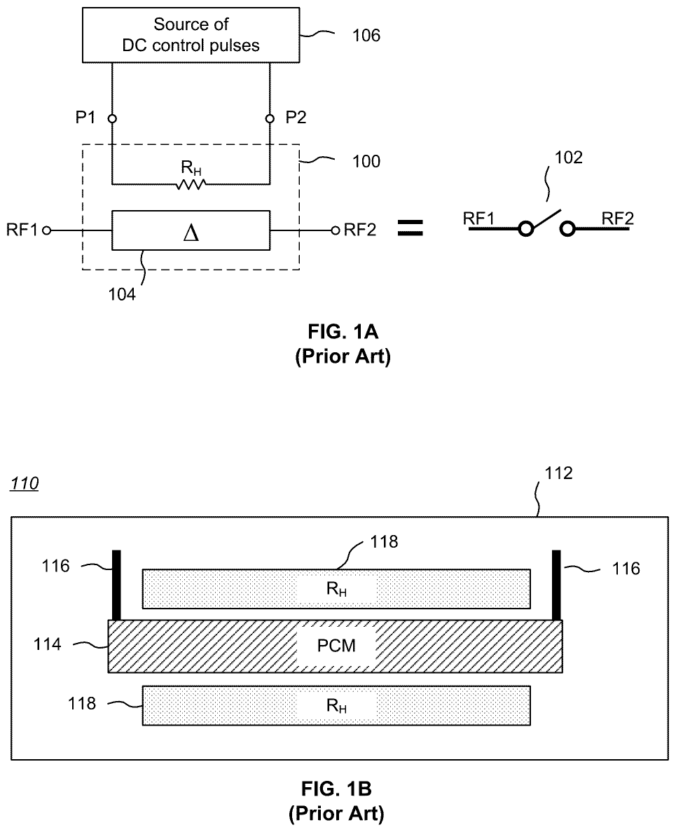

Like reference numbers and designations in the various drawings indicate like elements unless the context requires otherwise.

### DETAILED DESCRIPTION

The present invention encompasses circuits and methods for increasing the long-term reliability and performance of phase change material (PCM) switches. In particular, to overcome the effects of electromigration damage of the resistive heater(s) of a PCM switch and of the PCM layer itself, and thus improve long-term radio frequency (RF) performance and reliability, embodiments of the present invention apply an AC control pulse of equal power to a conventional DC control pulse.

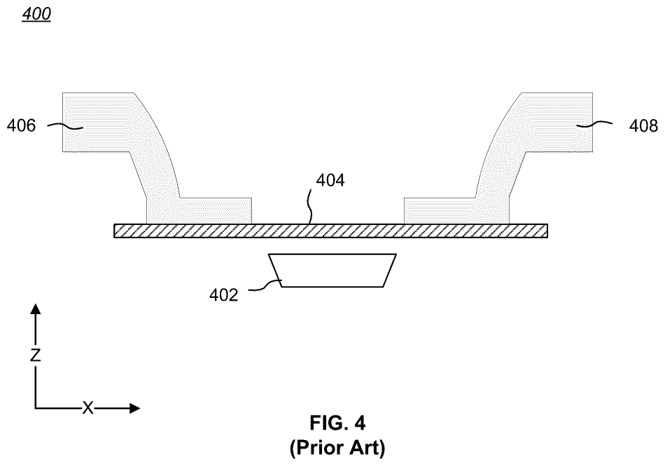

To better understand the problem addressed by the present invention, it is useful to understand the problem of electromigration damage to PCM switches. For example, FIG. 4 is a stylized cross-section of a PCM switch 400 in a pristine condition. In the illustrated example, a resistive heater 402 is positioned below a PCM layer 404. The resistive heater 402 may be made of a metal (e.g., copper, aluminum, nickel-chromium, or tungsten) or of any other material compatible with IC fabrication and which heats when electrical power is applied. An input contact 406 (e.g., Cu or Al) is connected to a first side of the PCM layer 404, and an output contact 408 (e.g., Cu or Al) is connected to a second side of the PCM layer 404. Electrical contacts to the resistive heater 402 are not shown in this cross-sectional view but generally would be made to the Y-axis edges of the resistive heater 402 (in and out of the page).

It may be noted that the resistive heater 402 has well-defined edges in FIG. 4, and that the PCM layer 404 is continuous and relatively uniform between the input contact 406 and the output contact 408. However, the unidirectional flow of DC power may cause electromigration within the resistive heater 402. Electromigration is the transport of material caused by the gradual movement of the ions in a conductor due to the momentum transfer between conducting electrons and diffusing metal atoms. In a PCM switch, electromigration over as few as about 10⁷ switching cycles may deform the shape of the resistive heater 402 and cause non-uniform heating of the adjacent PCM layer 404, resulting in damage to the PCM layer 404. As a result, a PCM switch may suffer from shorter amorphous areas which results in a decreased OFF-state power handling capability.

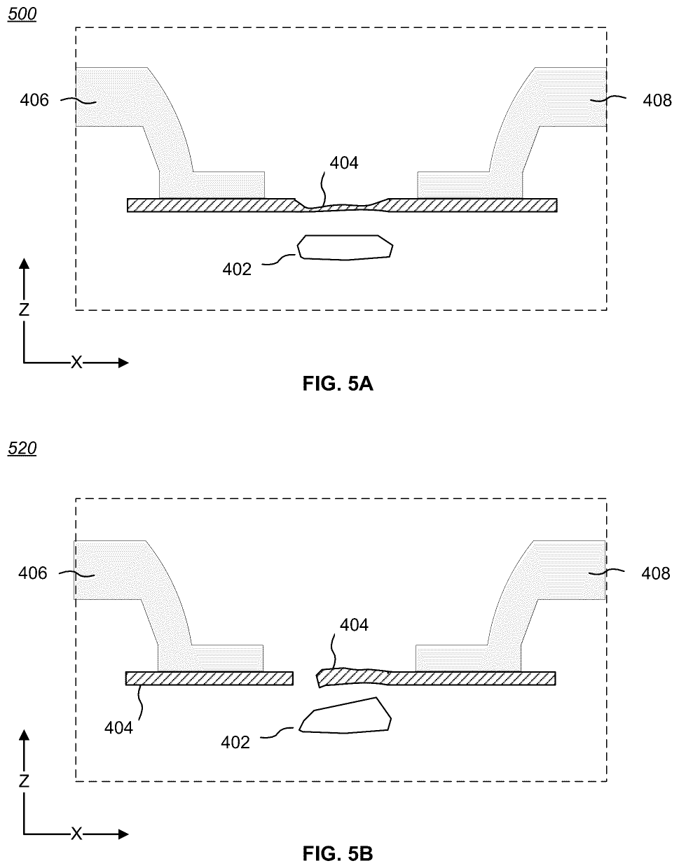

For example, FIGS. 5A and 5B are stylized cross-sections of two different PCM switches 500, 520 after failure due to electromigration. A comparison to the pristine PCM switch 400 of FIG. 4 shows badly deformed resistive heaters 402 and damage to the PCM layers 404 (including a complete breakage in FIG. 5B) due to electromigration.

To relieve the stress of electromigration on the resistive heater 402 of a PCM switch 400, embodiments of the present invention apply AC control pulses to the resistive heater 402 equal in power to corresponding conventional DC control pulses. The AC control pulses result in essentially a zero net momentum of the electrons within the resistive heater 402, thus eliminating or substantially mitigating the problem of electromigration.

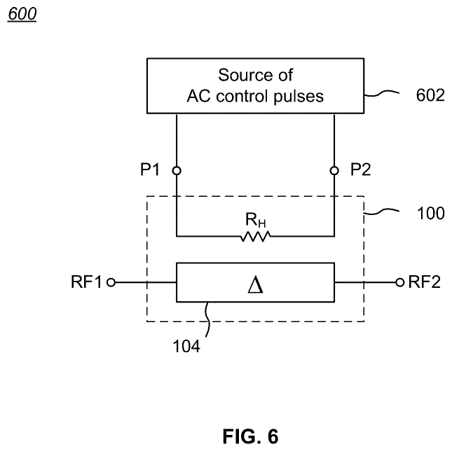

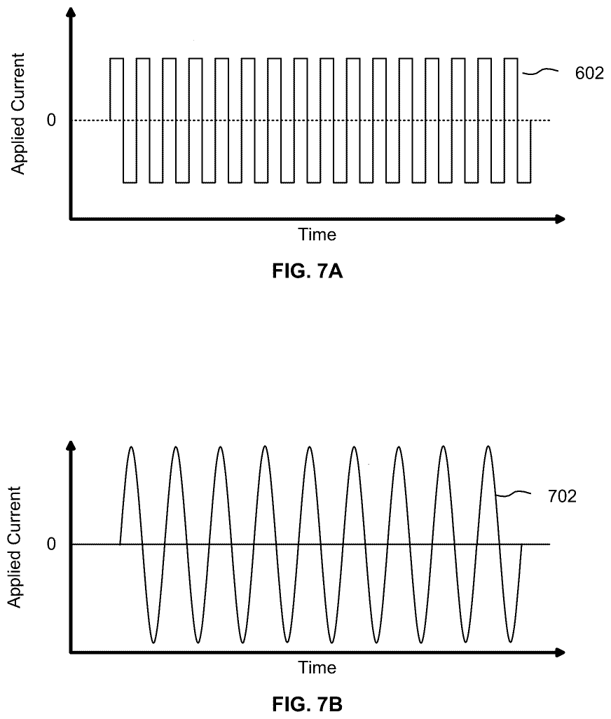

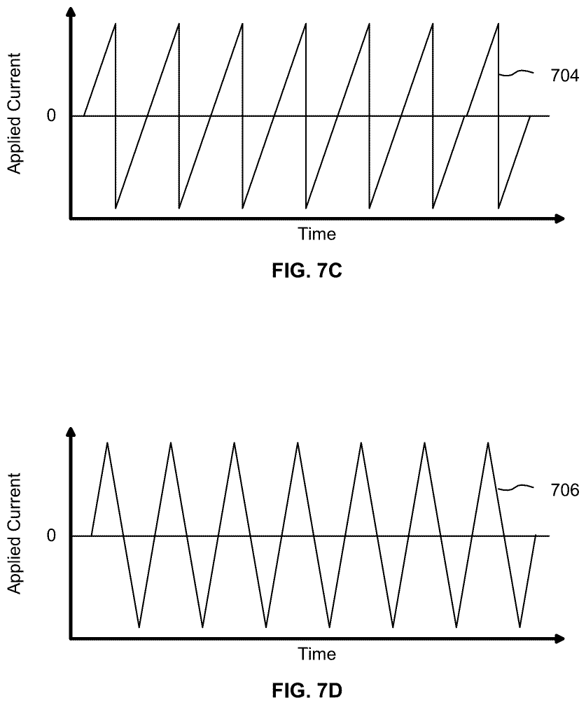

FIG. 6 is a schematic diagram 600 of a PCM switch including a source 602 of AC control pulses in accordance with the present invention. Ideally, the AC control pulses to the resistive heater 402—that is, the longer ON and shorter OFF pulses for the two desired thermal profiles in the PCM layer 404—would be rectangular waves. For example, FIG. 7A shows a graph of applied current as a function of time for AC control pulses comprising a sequence of rectangular waves 602. When the rectangular waves 602 are applied to a resistive heater 402, the heater will heat up regardless of the direction of current flow. Controlling the magnitude (plus and minus) of the rectangular waves 602 for the same duration of time used for DC ON/OFF control pulses can result in the same thermal profiles.

Preferably, the period of the rectangular waves 602 used for AC control pulses should change fast (e.g., 10× faster) compared to the temperature rise/fall time-constant of a PCM switch so that the PCM does not cool off significantly during periodic cycles. For example, if a PCM switch has a temperature rise time constant of about 50 ns, and if the rise/fall time of the rectangular waves 602 can be kept to about 5nsthen a relatively low frequency (e.g., 6 MHz) may be used, which may be easier to implement in an IC and be less prone to causing interference with other circuitry (internal and external).

While rectangular waves 602 for the AC control pulses may be ideal, other waveforms may be used—and may be easier to generate—for the AC control pulses, including sawtooth (ramp), triangular, and sinusoidal. Furthermore, particularly if a closed-loop temperature control circuit is utilized, the AC control pulses within the ON/OFF switching periods may be discontinuous—that is, AC control pulses may be applied for a portion of an ON or OFF switching period, then discontinued (i.e., a dead time), then restarted, so long as the corresponding temperature profile is achieved (that is, the dead time should be small compared with the temperature rise/fall time-constant of a PCM switch).

As examples of alternative non-rectangular waveforms, FIG. 7B shows a graph of applied current as a function of time for AC control pulses comprising a sequence of sinusoidal waves 702, FIG. 7C shows a graph of applied current as a function of time for AC control pulses comprising a sequence of sawtooth waves 704, and FIG. 7D shows a graph of applied current as a function of time for AC control pulses comprising a sequence of triangular waves 706. As should be clear, other waveforms may be used, including ramped waves (similar to amplitude-truncated triangular waves 706). Note that the waveforms shown in FIGS. 7A-7D are idealized; in practical circuits, the waveforms may not be as perfect, particularly at inflection points.

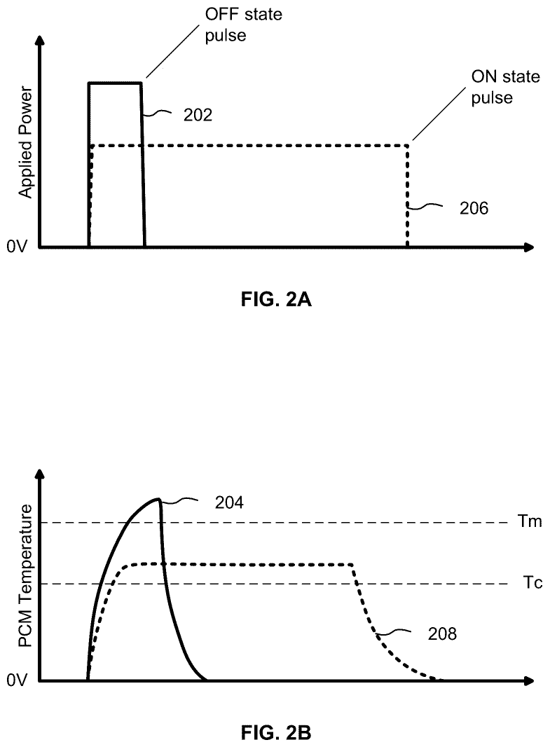

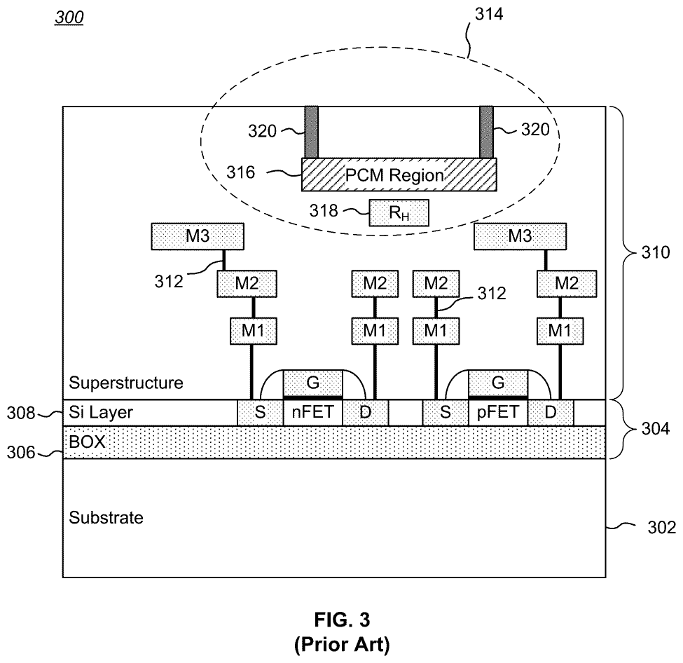

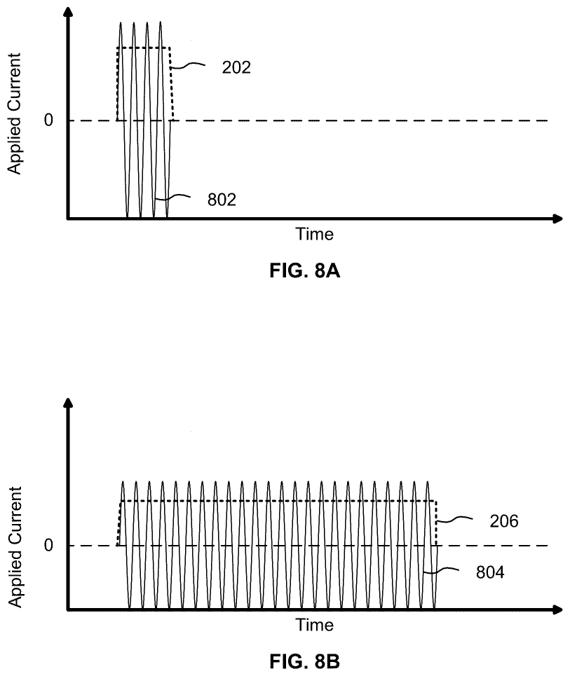

Since the average power per cycle of a non-rectangular wave is less than the average power per cycle of a rectangular wave of the same amplitude (root mean square (RMS) peak to DC peak), the magnitude of a non-rectangular waveform above and below a zero baseline generally has to be greater than a rectangular wave or a DC control pulse to deliver the same amount of power to the resistive heater 402 in the same amount of time. For example, FIG. 8A shows an example sinusoidal waveform 802 superimposed over the DC “OFF” control pulse 202 from FIG. 2A, and FIG. 8B shows an example sinusoidal waveform 804 superimposed over the DC “ON” control pulse 206 from FIG. 2A. In both figures, the RMS peak amplitude of the sinusoidal waveforms 802, 804 exceeds the peak amplitude of the corresponding DC control pulses 202, 206. In general, to achieve the same temperature profile in a PCM layer 404, if a rectangular-wave AC control pulse has a peak current density of J_{PK}, then the RMS peak current density of a sinusoidal-wave AC control pulse needs to be about J_{PK}×√2, or about 40% greater.

It is believed from analysis and experiment that the meantime-to-failure (MTTF) of a PCM switch using rectangular waves 602 for the AC control pulses would be approximately 1000× greater than the MTTF of a PCM switch using DC control pulses. Electromigration is also reduced when using easy-to-generate sinusoidal waves. It is believed from analysis and experiment that the MTTF of a PCM switch using sinusoidal waves 702 for the AC control pulses would be approximately 400× greater than a conventional PCM switch using DC control pulses. Notably, if a conventional PCM switch design using DC control pulses has an average MTTF of 10 million cycles, a 400× improvement in MTTF using sinusoidal waves 702 is about 4 billion cycles. Even an MTTF improvement of 50×—to about 500 million cycles—for a PCM switch using sinusoidal waves 702 for the AC control pulses would be a significant improvement in reliability compared to a PCM switch using DC control pulses.

Beyond electromigration mitigation, an additional benefit of applying an AC control pulse to a resistive heater 402 is better performance, especially when using AC-friendly components in a system. For example, an AC control pulse: (1) may be generated efficiently with different types of power amplifier circuits, allowing great flexibility in circuit design, (2) can traverse a DC blocking cap and grounded magnetics (e.g., a transformer or balun), enabling use of such circuit elements and increasing the range of possible circuit designs, (3) can be a differential control signal needing no AC ground at the terminals of the resistive heater 402, (4) may be implemented from a single external supply voltage so as to generate both the longer ON and shorter OFF pulses for the two desired thermal profiles in the PCM layer 404, such as by switching amplifier bias voltages between two levels or regulating the supply power to the amplifier, and (5) avoids coupling the parasitic capacitance of the PCM layer 404 and the resistive heater 402 to DC ground or an AC ground potential.

A wide variety of driver circuits may be used to provide AC control pulses to a resistive heater 402 of a PCM switch 400. Following are a number of specific circuit examples, but it should be appreciated that numerous other circuits may be used.

FIG. 9 is a schematic diagram of a first driver circuit 900 for generating AC control pulses for a resistive heater of a PCM switch. In the illustrated example, a sinusoidal voltage source 902 coupled to the control input of a switch 904 (e.g., a FET) through a resistor R connects a node X to circuit ground through a variable resistor R2 during half of each sinusoidal cycle, thereby discharging a capacitor C coupled to a resistive heater R_{H} and causing current to flow in a first direction through the resistive heater R_{H} while the capacitor C discharges. The sinusoidal voltage source 902 may be implemented using, for example, a sinusoidal oscillator, examples of which are commercially available. In half-cycles when node X is not connected to circuit ground, the capacitor C is charged from a voltage source V_{DC} through an inductor L, allowing current to flow through the resistive heater R_{H} in a second direction while the capacitor C charges. The amplitude of the power signals to the resistive heater R_{H} may be controlled by adjusting the resistance of R2, thus allowing the driver circuit 900 to generate both the longer ON and shorter OFF AC control pulses for the two desired thermal profiles in the PCM layer 404.

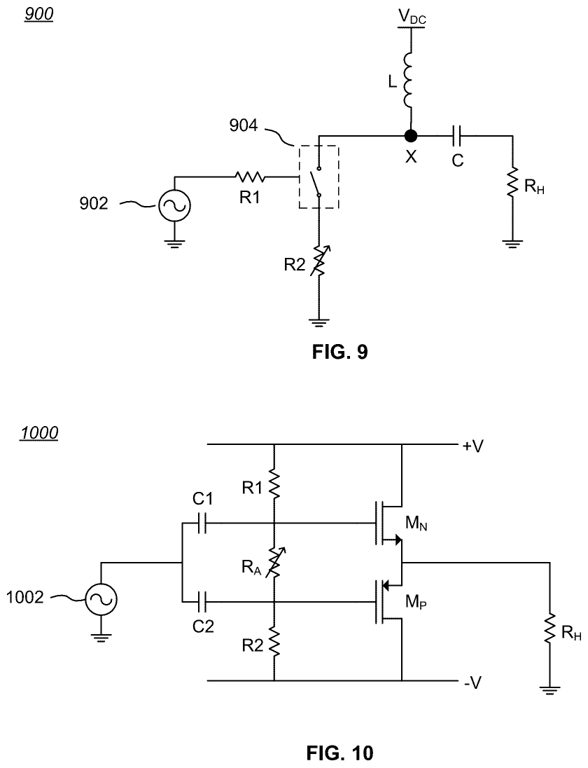

FIG. 10 is a schematic diagram of a second driver circuit 1000 for generating AC control pulses for a resistive heater of a PCM switch. In the illustrated example, the conduction channels (drain-to-source) of an NFET MN and a PFET M_{P} are coupled in series between a positive voltage rail V+ and a negative voltage rail V−. The gates of MN and M_{P} are coupled as shown to an adjustable resistive voltage divider circuit comprising resistors R1, RA (adjustable), and R2 coupled in series between the V+ and V− rails. The node between MN and M_{P} is coupled to a resistive heater R_{H}. The node between R1 and RA is coupled to a sinusoidal voltage source 1002 through a DC blocking capacitor C1, and the node between RA and R2 is coupled to the sinusoidal voltage source 1002 through a DC blocking capacitor C2. In a positive half-cycle of the sinusoidal voltage source 1002, only MN conducts and provides power to the resistive heater R_{H} in a first direction. In a negative positive half-cycle of the sinusoidal voltage source 1002, only M_{P} conducts and provides power to the resistive heater R_{H} in a second direction. The amplitude of the power signals to the resistive heater R_{H} may be controlled by adjusting the resistance of RA, thus allowing the driver circuit 1000 to generate both the longer ON and shorter OFF AC control pulses for the two desired thermal profiles in the PCM layer 404.

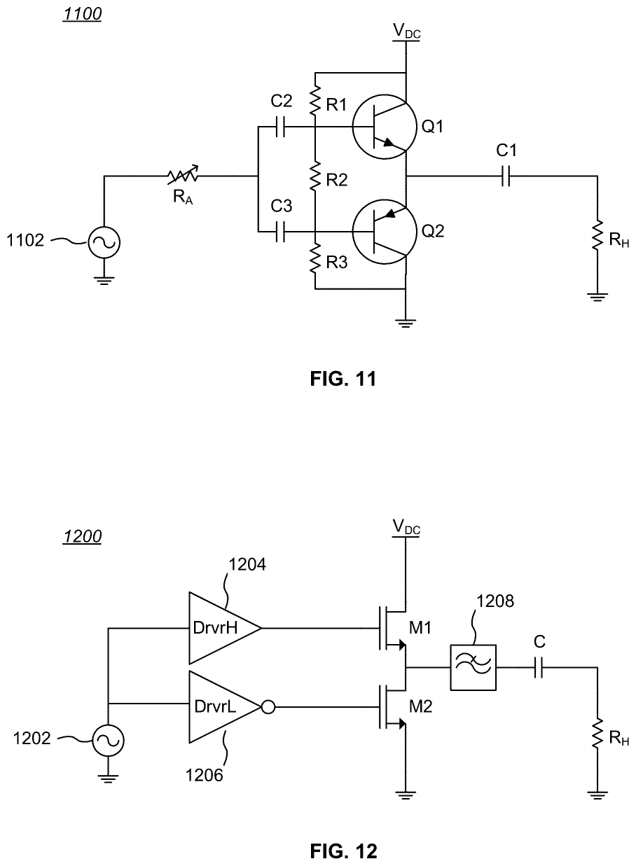

FIG. 11 is a schematic diagram of a third driver circuit 1100 for generating AC control pulses for a resistive heater of a PCM switch. The illustrated example is essentially a bipolar junction transistor (BJT) version of the driver circuit 1000 of FIG. 10. The conduction channels (collector-to-emitter) of an NPN BJT Q1 and a PNP BJT Q2 are coupled in series between a voltage source V_{DC} and circuit ground (or alternatively to −V_{DC}). The node between Q1 and Q2 is coupled to a resistive heater R_{H} (through capacitor C1 if the collector of Q2 is coupled to circuit ground).

Voltage source 1102 provides an AC waveform to Q1 and Q2 through an adjustable resistor RA and DC blocking capacitors C2 and C3. Resistors R1, R2, and R3 set bias voltages on transistors Q1 and Q2 such that when no AC signal is present, current drain through the transistors is minimized. The voltage at the emitters of Q1 and Q2 will be approximately V_{DC}/2 when there is minimal current flow, assuming Q2 is connected to ground.

If the Q2 collector-R3 junction is connected to a −V_{DC} voltage and not ground, the voltage at the emitters of Q1 and Q2 will be equal to (V_{DC}+(−V_{DC}))/2 when current through the transistors is minimum. If V_{DC} and −V_{DC} are equal in magnitude, this voltage will equal 0V. Resistors R1, R2, and R3 also ensure the bias voltages at the bases of Q1 and Q2 are adjusted to minimize distortion of the AC waveform.

If the Q2 collector-R3 junction is grounded, then during the part of the cycle when the AC waveform is greater than 0V, transistor Q1 will push current from V_{DC} through capacitor C1 to heater R_{H}. Q2 will be OFF during this part of the AC waveform. When the AC waveform is less than 0V, Q2 will pull current from capacitor C1 through R_{H} and back to ground. Q1 will be OFF during this part of the waveform.

If the Q2 collector-R3 junction is connected to −V_{DC}, then during the part of the cycle when the AC waveform is greater than 0V, Q1 will pull current from V_{DC} through capacitor C1 to the heater R_{H}. Q2 will be OFF during this part of the AC waveform. When the AC waveform is less than 0V, Q2 will push current to −V_{DC} from ground through the through capacitor C1 and heater R_{H}. Q1 will be OFF during this part of the AC waveform.

The amplitude of the power signals to the resistive heater R_{H} may be controlled by adjusting the resistance of RA, while the duration of such power signals may be controlled by timing the output of the voltage source 1102, thus allowing the driver circuit 1100 to generate both the longer ON and shorter OFF AC control pulses for the two desired thermal profiles in the PCM layer 404.

FIG. 12 is a schematic diagram of a fourth driver circuit 1200 for generating AC control pulses for a resistive heater of a PCM switch. In the illustrated example, the conduction channels (drain-to-source) of two NFETs M1 and M2 are coupled in series between a voltage source V_{DC} and circuit ground. The gate of M1 is coupled to a non-inverting high-side driver circuit 1204 and the gate of M2 is coupled to an inverting low-side driver circuit 1206. The node between M1 and M2 is coupled to a resistive heater R_{H} through capacitor C. The inputs to the driver circuits 1204, 1206 are coupled to a sinusoidal voltage source 1202. In a positive half-cycle of the sinusoidal voltage source 1202, only M1 conducts and charges capacitor C, allowing current to flow through the resistive heater R_{H} in a first direction while the capacitor C charges. In a negative half-cycle of the sinusoidal voltage source 1202, only M2 conducts and discharges capacitor C, allowing current to flow through the resistive heater R_{H} in a second direction while the capacitor C discharges. The amplitude of the power signals to the resistive heater R_{H} may be controlled by adjusting the driver circuits DrvrH and DrvrL, thus allowing the driver circuit 1200 to generate both the longer ON and shorter OFF AC control pulses for the two desired thermal profiles in the PCM layer 404. Alternatively, NFETS for M1 and M2 may each include numerous interdigitated source and drain “fingers” and a corresponding set of interposed gates that enables selection of different current levels by activating larger or smaller sets of channels. Accordingly, the effective width W of M1 and M2 may be controlled depending on the ON or OFF pulse desired. Some embodiments, particularly RF systems, may include a low-pass filter 1208 to filter out harmonic frequencies from the AC control pulses (note that such a filter may be useful for other embodiments, including those shown in FIGS. 9-11, 13A, and 14-15).

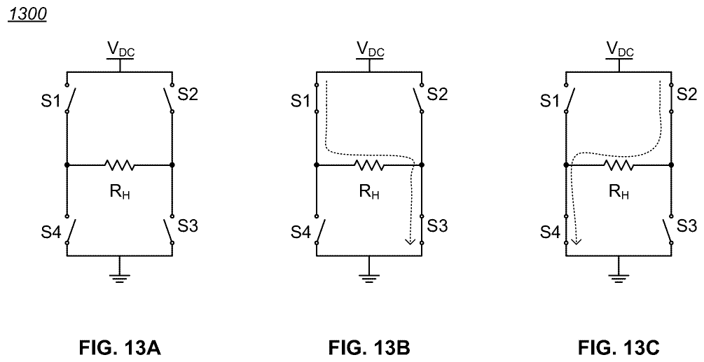

FIG. 13A is a schematic diagram of a fifth driver circuit 1300 for generating AC control pulses for a resistive heater of a PCM switch. The illustrated example shows an H-Bridge circuit comprising switches S1 and S4 coupled in series between a voltage source V_{DC} and circuit ground, and switches S2 and S3 coupled in series between the voltage source V_{DC} and circuit ground, where the S1/S4 pair of switches are in parallel with the S2/S3 pair of switches. A resistive heater R_{H} is coupled between a node between the S1 and S4 switches and a node between the S2 and S3 switches. The switches S1-S4 may be, for example, a suitable combination of NFETs and/or PFETs or may be implemented with other types of switching technology, including BJTs or MEMS switches. A set of control signals provided from a controller (not shown) would set the state of switches S1 and S3 as a pair and the state of switches S2 and S4 as a pair.

FIG. 13B is a schematic diagram of the driver circuit 1300 shown during a first half cycle, with switch pair S1/S3 closed and switch pair S2/S4 open. Consequently, current from V_{DC} flows in a first direction through the resistive heater R_{H}. FIG. 13C is a schematic diagram of the driver circuit 1300 shown during a second half cycle, with switch pair S1/S3 open and switch pair S2/S4 closed. Consequently, current from V_{DC} flows in a second direction through the resistive heater R_{H}. When switches S1-S4 are all open, the resistive heater R_{H} is in an isolated state.

An H-Bridge circuit has the advantage of needing no DC blocking capacitor. Further, since the resistive heater R_{H} has no AC or DC ground connection, the H-Bridge circuit should have reduced parasitic capacitance between the PCM layer 404 and ground, which should reduce PCM switch insertion loss. The supply voltage V_{DC} to the H-Bridge may be varied depending on the required heater voltage to turn the PCM switch ON or OFF.

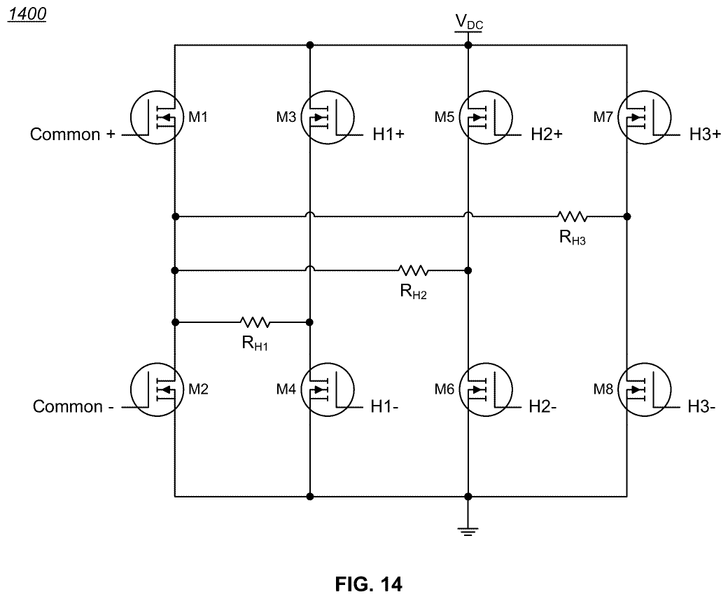

FIG. 14 is a schematic diagram of a sixth driver circuit 1400 for generating AC control pulses for a resistive heater of a PCM switch. The illustrated example shows a shared H-Bridge circuit that can drive multiple resistive heaters R_{H} without the need for a complete H-Bridge for each resistive heater R_{H}. In the illustrated example, a first set of NFET switches M1 and M2 are coupled in series between a voltage source V_{DC} and circuit ground and controlled by respective signals Common+ and Common−. A second set of NFET switches M3 and M4 are similarly coupled between V_{DC} and circuit ground and are controlled by respective signals H1+ and H1−. A first resistive heater R_{H1} is coupled to respective nodes between M1 and M2 and between M3 and M4 as shown.

More transistor pairs and resistive heaters may be added as required for a particular application. Thus, in this example: a third set of NFET switches M5 and M6 are coupled between V_{DC} and circuit ground and are controlled by respective signals H2+ and H2−, with a second resistive heater R_{H2} coupled to respective nodes between M1 and M2 and between M5 and M6; and a fourth set of NFET switches M7 and M8 are coupled between V_{DC} and circuit ground and are controlled by respective signals H3+ and H3−, with a third resistive heater R_{H3} coupled to respective nodes between M1 and M2 and between M7 and M8. While NFET embodiments of the various switches are illustrated, the shared H-Bridge circuit may be implemented using any suitable combination of NFETs and/or PFETs.

As should be appreciated, resistive heater R_{H1} and switches M1-M4 are essentially a first instance of an H-Bridge circuit, resistive heater R_{H2} and switches M1, M2, M5, M6 are essentially a second instance of an H-Bridge circuit, and resistive heater R_{H3} and switches M1, M2, M7, M8 are essentially a third instance of an H-Bridge circuit. Thus, the three instances of the H-Bridge circuit all share switches M1 and M2.

A set of control signals provided from a controller (not shown) would set the state of the switches in a manner similar to the H-Bridge circuit of FIG. 13A. Thus, power may be provided to any one or more resistive heater R_{Hn} in a first direction by applying the Common+ signal to turn on M1 and applying the opposite-polarity control signal Hₙ− to turn on the corresponding “low side” switch (e.g., M4, M6, or M8); all other switches would be set to an open state. Similarly, power may be provided to any one or more resistive heater R_{Hn} in a second direction by applying the Common-signal to turn on M2 and applying the opposite-polarity control signal Hₙ+ to turn on the corresponding “high side” switch (e.g., M3, M5, or M7); all other switches would be set to an open state. The controller would alternate current flow directions to provide the desired AC pulses through the resistive heater R_{Hn}. The supply voltage V_{DC} to the H-Bridge may be varied depending on the required heater voltage to turn the PCM switch ON or OFF.

Note that M1 and M2 are preferably always ON longer than the individual heater pulse transistors. This allows for the individual heater transistors to be used to set the pulse timing of each resistive heater R_{Hn} as well as which resistive heaters R_{Hn} are driven. Note that M1 and M2 may need to be sized to handle more current than the other transistors since M1 or M2 may have current from multiple resistive heater R_{Hn} flow through at the same time. The other devices in the circuit (e.g., M3 to M8) only need to handle the current from one heater at a time and may be sized smaller than M1 and M2.

The circuit in FIG. 14 may be used to control multiple switch heaters at the same time as long as all of the PCM switches driven by multiple heaters are put into the same state at the same time. They should not be put into different states because the heater voltages required to put the PCM switch in an ON state and OFF state may be different. As should be clear, combinations of PCM switches may need to be controlled in specific orders so as to avoid shorts to ground.

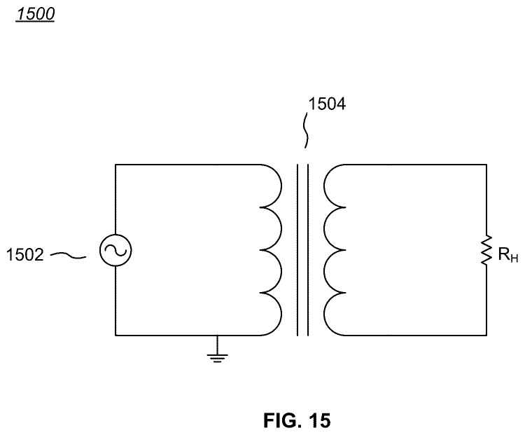

FIG. 15 is a schematic diagram of a seventh driver circuit 1500 for generating AC control pulses for a resistive heater of a PCM switch. The illustrated example shows an AC signal source 1502 referenced to ground (e.g., one of the circuits shown in FIGS. 9-12, 13A and 14 above) coupled to a first side of an isolation element 1504 comprising a transformer or a balun. A resistive heater R_{H} is coupled to the second side of the isolation element 1504.

The AC signal source 1502 may be single-ended or differential. If the AC signal source 1502 is single-ended, the differential circuit provides the AC characteristics of the control signal. If the AC signal source 1502 is already differential, the isolation element 1504 provides a higher common mode impedance seen by the resistive heater R_{H}. A high common mode impedance means that the resistive heater R_{H} is essentially floating with respect to a signal (e.g., an RF signal) traversing the PCM layer 404 between ports RF1 and RF2 of a PCM switch 400.

A differentially-driven resistive heater R_{H} improves reliability of a PCM switch by mitigating electromagnetic interference, and improves performance because of the floating common mode (parasitics not going to ground). Other advantages include flexibility in IC layouts. For example, PCM switches may be coupled in parallel or stacked in series or coupled to switches with the same logic, with the heaters connected in series—while there may be a constraint on voltage handling, routing may be simplified.

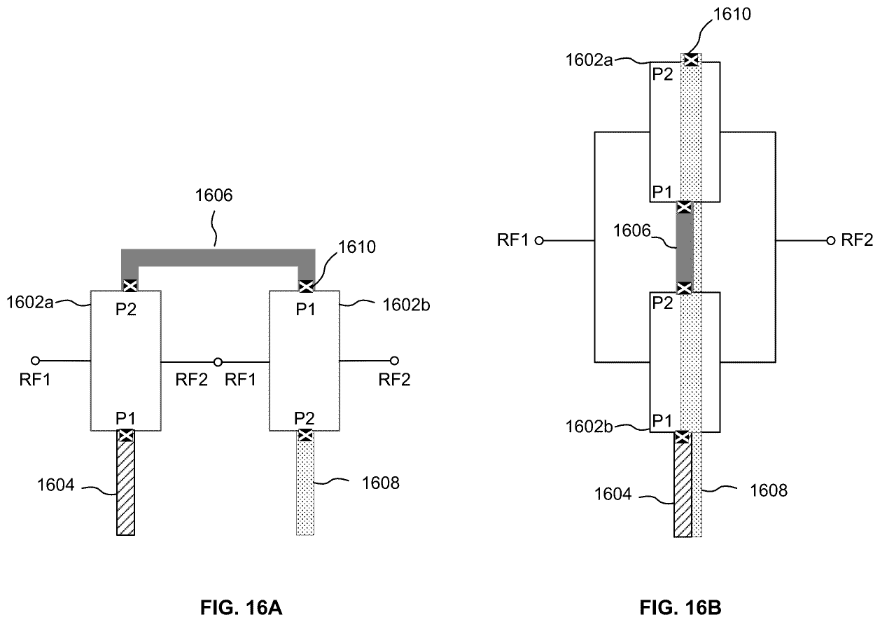

For example, FIG. 16A is a schematic layout diagram of a pair of PCM switches 1602a, 1602b with RF ports connected in series and corresponding resistive heaters connected in series. As another example, FIG. 16B is a schematic layout diagram of a pair of PCM switches 1602a, 1602b with RF ports connected in parallel and corresponding resistive heaters connected in series. The input 1604, inter-heater connector 1606, and output 1608 connections for the resistive heaters may be laid out in different metallization layers within the superstructure of an IC, as suggested by the different shadings, with vias 1610 completing the electrical connections to the resistive heaters (not all vias are labeled to avoid clutter). In FIG. 16B, the output 1608 connection is shown as behind the PCM switches 1602a, 1602b, as indicated by the dashed “phantom” lines.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

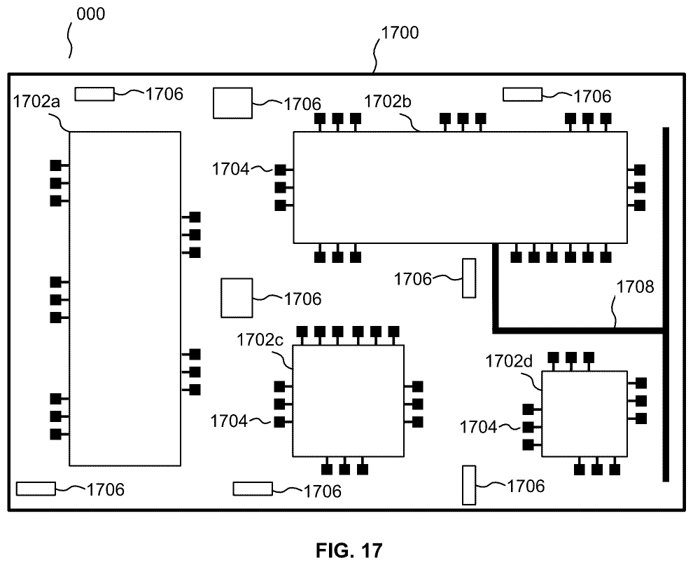

As one example of further integration of embodiments of the present invention with other components, FIG. 17 is a top plan view of a substrate 1700 that may be, for example, a printed circuit board or chip module substrate (e.g., a thin-film tile). In the illustrated example, the substrate 1700 includes multiple ICs 1702a-1702d having terminal pads 1704 which would be interconnected by conductive vias and/or traces on and/or within the substrate 1700 or on the opposite (back) surface of the substrate 1700 (to avoid clutter, the surface conductive traces are not shown and not all terminal pads are labelled). The ICs 1702a-1702d may embody, for example, signal switches, active and/or passive filters, amplifiers (including one or more LNAs), and other circuitry. For example, IC 1702b may incorporate one or more instances of a PCM switch configured to be switched ON or OFF by AC control pulses.

The substrate 1700 may also include one or more passive devices 1706 embedded in, formed on, and/or affixed to the substrate 1700. While shown as generic rectangles, the passive devices 1706 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1700 to other passive devices 1706 and/or the individual ICs 1702a-1702d.

The front or back surface of the substrate 1700 may be used as a location for the formation of other structures. For example, one or more antennae may be formed on or affixed to the front or back surface of the substrate 1700; one example of a front-surface antenna 1708 is shown, coupled to an IC die 1702b, which may include RF front-end circuitry. Thus, by including one or more antennae on the substrate 1700, a complete radio receiver, transmitter, or transceiver may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

Another aspect of the invention includes methods for changing the resistance state of a phase change material (PCM) switch. For example, a first such method includes selectively applying AC control pulses to a resistive heater adjacent to a PCM region of the PCM switch, the AC control pulses having a first power profile to transform the PCM region into a low resistance state and a second power profile to transform the PCM region into a high resistance state.

A second such method includes selectively applying AC control pulses to a resistive heater adjacent to a PCM region of the PCM switch, the AC control pulses including a first set of AC control pulses to transform the PCM region into a low resistance state, and a second set of AC control pulses to transform the PCM region into a high resistance state.

Additional aspects of the above method may include one or more of the following: wherein the first power profile comprises a set of high-power, short-period AC control pulses to transform the PCM region into a high resistance state; wherein the second power profile comprises a set of low-power, long-period AC control pulses to transform the PCM region into a low resistance state; wherein the first power profile comprises a first set of high-power, short-period AC control pulses to transform the PCM region into a high resistance state, and the second power profile comprises a second set of low-power, long-period AC control pulses to transform the PCM region into a low resistance state; wherein the AC control pulses have one of a rectangular waveform, a sinusoidal waveform, a sawtooth waveform, or a triangular waveform; wherein the AC control pulses are generated by an H-Bridge circuit coupled to the resistive heater; wherein the first set of AC control pulses comprises high-power, short-period AC control pulses to transform the PCM region into a high resistance state; wherein the second set of AC control pulses comprises low-power, long-period AC control pulses to transform the PCM region into a low resistance state; wherein the first set of AC control pulses comprises high-power, short-period AC control pulses to transform the PCM region into a high resistance state, and the second set of AC control pulses comprises low-power, long-period AC control pulses to transform the PCM region into a low resistance state.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BICMOS, LDMOS, BCD, GaAs HBT, GaN HEMT, GaAs pHEMT, MESFET, InP HBT, InP HEMT, FinFET, GAAFET, and SiC-based device technologies, using 2-D. 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHZ). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A phase change material (PCM) switch, including:
(a) a PCM region including first and second signal ports configured to be coupled to a signal source;
(b) a resistive heater adjacent the PCM region and including first and second heater control signal ports;
(c) a source of AC control pulses coupled to the first and second heater control signal ports the AC control pulses having a first power profile to transform the PCM region into a high resistance state and a second power profile to transform the PCM region into a low resistance state.

2. The invention of claim 1, wherein the first power profile comprises a set of high-power, short-period AC control pulses to transform the PCM region into a high resistance state.

3. The invention of claim 1, wherein the second power profile comprises a set of low-power, long-period AC control pulses to transform the PCM region into a low resistance state.

4. The invention of claim 1, wherein the first power profile comprises a first set of high-power, short-period AC control pulses to transform the PCM region into a high resistance state, and the second power profile comprises a second set of low-power, long-period AC control pulses to transform the PCM region into a low resistance state.

5. The invention of claim 1, wherein the AC control pulses have a rectangular waveform.

6. The invention of claim 1, wherein the AC control pulses have a sinusoidal waveform.

7. The invention of claim 1, wherein the AC control pulses have a sawtooth waveform.

8. The invention of claim 1, wherein the AC control pulses have a triangular waveform.

9. The invention of claim 1, wherein the source of AC control pulses includes an H-Bridge circuit coupled to the first and second heater control signal ports.

10. A phase change material (PCM) switch, including:
(a) a PCM region including first and second signal ports configured to be coupled to a signal source;
(b) a resistive heater adjacent the PCM region and including first and second heater control signal ports;
(c) a source of AC control pulses coupled to the first and second heater control signal ports and configured to selectively output a first set of AC control pulses to transform the PCM region into a high resistance state and a second set of AC control pulses to transform the PCM region into a low resistance state.

11. The invention of claim 10, wherein the first set of AC control pulses comprises high-power, short-period AC control pulses to transform the PCM region into a high resistance state.

12. The invention of claim 10, wherein the second set of AC control pulses comprises low-power, long-period AC control pulses to transform the PCM region into a low resistance state.

13. The invention of claim 10, wherein the first set of AC control pulses comprises high-power, short-period AC control pulses to transform the PCM region into a high resistance state, and the second set of AC control pulses comprises low-power, long-period AC control pulses to transform the PCM region into a low resistance state.

14. The invention of claim 10, wherein the AC control pulses have a rectangular waveform.

15. The invention of claim 10, wherein the AC control pulses have a sinusoidal waveform.

16. The invention of claim 10, wherein the AC control pulses have a sawtooth waveform.

17. The invention of claim 10, wherein the AC control pulses have a triangular waveform.

18. The invention of claim 10, wherein the source of AC control pulses includes an H-Bridge circuit coupled to the first and second heater control signal ports.

19.-36. (canceled)
